(19) United States
(12) Patent Application Publication
(10) Pub. No.: US 2017/0125747 A1
(43) Pub. Date: May 4, 2017

(54) METAL HALIDE PEROVSKITE LIGHT EMITTING DEVICE AND METHOD OF MANUFACTURING THE SAME

(71) Applicant: POSTECH ACADEMY - INDUSTRY FOUNDATION, Pohang-si (KR)

(72) Inventors: Tae-Woo Lee, Pohang-si (KR); Minho Park, Incheon (KR)

(21) Appl. No.: 15/289,022

(22) Filed: Oct. 7, 2016

(30) Foreign Application Priority Data
Oct. 30, 2015 (KR) 10-2015-0152553

(51) Int. Cl. H01L 51/56; H01L 51/00; C09K 11/06; H01L 51/50

(52) U.S. Cl. CPC H01L 51/56; H01L 51/5072; H01L 51/0007; C09K 11/06; H01L 51/5012; H01L 51/5016; H01L 51/0077; C09K 2211/188; H01L 51/0061; H01L 51/0072; H01L 51/0037; H01L 51/0035

(57) ABSTRACT

Provided are a metal halide perovskite light emitting device and a method of manufacturing the same. The method of manufacturing a metal halide perovskite light emitting device includes preparing a substrate having a positive electrode formed on an upper part thereof, starting coating the substrate on which the positive electrode is formed with a metal halide perovskite light emitting layer, forming a metal halide perovskite light emitting layer by dripping a low-molecular-weight organic substance solution during the coating of the metal halide perovskite light emitting layer, and forming a negative electrode on the light emitting layer. According to the present invention, a low-molecular-weight organic substance is included in a metal halide perovskite light emitting layer to reduce the sizes of grains in metal halide perovskites, to improve electrical characteristics by the effect of defect passivation on a metal halide perovskite, and to improve luminous efficiency of a thin film by reducing an exciton diffusion length by spatially trapping excitons well in decreased grains, thereby effectively improving efficiency of a metal halide perovskite light emitting diode and overcoming limitations in application.

### CROSS-REFERENCE TO RELATED APPLICATION

This application claims priority to and the benefit of Korean Patent Application No. 10-2015-0152553, filed on Oct. 30, 2015, the disclosure of which is incorporated herein by reference in its entirety.

### BACKGROUND

1. Field of the Invention

The present invention relates to a metal halide perovskite light emitting device and a method of manufacturing the same, and more particularly, to a metal halide perovskite light emitting device having improved luminous efficiency, and a method of manufacturing the same.

2. Discussion of Related Art

In recent years, the display industry has been changed from inorganic light emitting diodes (LEDs) to organic light emitting diodes. The organic light emitting diodes have characteristics such as a relatively simple and lightweight structure and processability as well as a flexibility, and thus have come into the spotlight as next-generation flexible electronic devices. Meanwhile, inorganic quantum dot materials, following organic light emitting diodes, have come into the spotlight due to their advantages such as high color purity.

However, although organic light emitting diodes have high efficiency, they have a drawback in that color purity may deteriorate due to a wide full width at half maximum of an emission spectrum, and while inorganic quantum dots in which color is adjusted according to the size of the quantum dots have high color purity, they have a drawback in that it is very difficult to adjust the size of the quantum dot during a synthesis process. Also, organic light emitting diodes and inorganic quantum dot materials have a limitation in manufacturing low-priced products due to their high manufacturing costs. Therefore, research on perovskite light emitting diodes which exhibit high color purity, are manufactured in a simple process, and have a low manufacturing cost is needed.

In particular, metal halide perovskite materials have advantages in that they have a low unit price, are synthesized in a very simple method, and can be subjected to a solution process. Also, metal halide perovskite materials have photoluminescence and electroluminescence characteristics, and thus can be applied to light emitting diodes.

A metal halide perovskite has an ABX₃ structure, and is in the form of a combination of face-centered cubic (FCC) and body-centered cubic (BCC) structures. Halogen elements such as Cl, Br, I, or a combination thereof are positioned at the X sites, an organic ammonium (RNH₃) cation or monovalent alkali metal ion is positioned at the A site, and a metal element (an alkali metal, an alkali earth metal, a transition metal, etc.) such as Pb, Mn, Cu, Ge, Sn, Ni, Co, Fe, Cr, Pd, Cd, or Yb is positioned at the B sites.

The metal halide perovskite may have a structure of A₂BX₄, ABX₄ or Aₙ₋₁PbₙI₃ₙ₊₁ (n is an integer ranging from 2 to 6), all of which have a lamellar-type two-dimensional structure.

Here, A is an organic ammonium material, B is a metal material, and X is a halogen element. For example, A may be (CH₃NH₃)ₙ, ((CₓH₂ₓ₋₁)ₙNH₃)₂(CH₃NH₃)ₙ, (RNH₃)₂, (CₙH₂ₙ₊₁NH₃)₂, (CF₃NH₃), (CF₃NH₃)ₙ, ((CₓF₂ₓ₊₁)ₙNH₃)₂(CF₃NH₃)ₙ, ((CₓF₂ₓ₊₁)ₙNH₃)₂, or (CₙF₂ₙ₊₁NH₃)₂ (n is an integer greater than or equal to 1), and B may be a divalent transition metal, a rare earth metal, an alkaline earth metal, Pb, Mn, Cu, Ni, Co, Pd, Cd, Sn, Ge, Ga, In, Al, Sb, Bi, Po, or a combination thereof. In this case, the rare earth metal may, for example, be Ge, Sn, Pb, Eu, or Yb. Also, the alkaline earth metal may, for example, be Ca or Sr. In addition, X may be Cl, Br, I, or a combination thereof.

As such, metal halide perovskites include organic metal halide perovskites having an organic substance at the A site. An organic metal halide perovskite is similar to an inorganic metal oxide having a perovskite structure (ABX₃) in that both of them have a perovskite crystal structure, but actually has quite different compositions and characteristics from inorganic metal oxide. An inorganic metal oxide is generally an oxide which does not include a halide, that is, a material in which metal (alkali metal, alkali earth metal, transition metal, lanthanide, etc.) cations having different sizes, such as Ti, Sr, Ca, Cs, Ba, Y, Gd, La, Fe, Mn, etc., are positioned at the A and B sites, and the metal cations at the B site are bound to O (oxygen) anions in the form of a corner-sharing octahedron with 6-fold coordination. Examples of inorganic metal oxides include SrFeO₃, LaMnO₃, CaFeO₃, etc. On the other hand, an organic metal halide perovskite has a structure in which an organic ammonium (RNH₃) cation is positioned at the A site and halides (Cl, Br, and I) are positioned at the X sites, and thus has quite a different composition from an inorganic metal oxide. The characteristics of materials differ depending on a difference in such components. An inorganic metal oxide typically has characteristics such as superconductivity, ferroelectricity, colossal magnetoresistance, etc., and thus generally has been studied to be applicable to sensors, fuel cells, memory devices, etc. As an example, yttrium barium copper oxide has either a superconducting or insulating property, depending on oxygen content.

On the other hand, since an organic metal halide perovskite has a lamellar structure in which organic and inorganic planes are alternately stacked, and enables excitons to be trapped in the inorganic plane, the organic metal halide perovskite may be essentially an ideal phosphor that emits light having very high color purity, depending on the crystal structure itself rather than the size of the material.

Even in the case of an organic metal halide perovskite, when the organic ammonium includes a chromophore having a smaller band gap than a core metal and a halogen crystal structure (BX₃), light emission is generated in the organic ammonium. As a result, since the light emission in the organic ammonium does not have high color purity (a full width at half maximum of less than 30 nm), the full width at half maximum of a light emission spectrum should be wider than 50 nm, which makes the organic metal halide perovskite unsuitable for light emitting layers. Therefore, in this case, the organic metal halide perovskite is very unsuitable for phosphors having high color purity (a full width at half maximum of less than 30 nm) emphasized in this patent application. Accordingly, it is important that the organic ammonium does not include a chromophore and that light emission occur in an inorganic lattice composed of a core metal and a halogen element in order to prepare a phosphor having high color purity. This is because the band gap between the valence band maximum and the conducting band minimum of the material does not depend on an organic ligand, but depends on the core metal and halide atoms. Therefore, this patent application has focused on development of phosphors of high color purity and high efficiency in which light emission occurs in the inorganic lattice.

Although such a metal halide perovskite has advantages as a light emitting diode, the metal halide perovskite has a problem of limitations in application to light emitting diodes.

First, a problem such as a decline in efficiency of a light emitting diode is caused due to various types of defects present inside perovskites. Since a point-defect-type trap and a linear grain boundary enable electrons and holes to be non-radiatively recombined to emit energy as heat, luminous efficiency may be reduced in both the solar cell and the light emitting diode. That is, since such defects exist out of an energy level of a conduction band or a valence band, the electrons or holes are trapped at an energy level of the defects to limit movement of charges and induce unwanted non-radiative recombination.

Second, an exciton recombination rate is determined by the size of grains. That is, as the size of grains in perovskites decreases, a diffusion length of charges decreases, and a quantity of the charges present in the grains increases, resulting in an increased recombination rate. Therefore, it is important to effectively reduce the size of the grains, compared to those in the art.

Third, metal halide perovskite materials are known to have p-type characteristics. In particular, metal halide perovskite materials have been reported as materials which are not thermodynamically converted into the n-type when Br is used, and thus are known to exhibit p-type characteristics. In light emitting diodes in which the balance between the electrons and the holes is important, perovskites having only p-type characteristics have a problem in that they can only exhibit low efficiency.

Fourth, metal halide perovskite thin films often prepared for conventional solar cells are known to have a low exciton binding energy (<50 nm) and a very long exciton diffusion length (>100 nm). However, an increase in the exciton binding energy and a decrease in the exciton diffusion length should be achieved to enhance luminous efficiency. In this way, a metal halide perovskite thin film has a drawback in that it is difficult to implement using a thin film manufacturing process (in which a device having higher efficiency has a higher grain size (>200 nm) and severe surface unevenness) used in metal halide solar cells known in the art.

### PRIOR-ART DOCUMENTS

### Patent Documents

(Patent Document 1) Korean Patent Unexamined Publication No. 10-2014-0009939

### SUMMARY OF THE INVENTION

Embodiments of the present invention provide a metal halide perovskite light emitting diode and a method of manufacturing the same in which metal halide perovskites have a decreased grain size, and that has the effect of defect passivation on the metal halide perovskites and improved electrical characteristics, through a two-step process in which an organic solution in which a low-molecular-weight organic substance is dissolved in a small amount in an organic solvent is additionally applied before a solvent is removed from a light emitting layer during formation of a metal halide perovskite light emitting layer.

In an aspect of the present invention, a method of manufacturing a metal halide perovskite light emitting device is provided. The method of manufacturing a metal halide perovskite light emitting device may include preparing a substrate having a positive electrode formed on an upper part thereof, forming a metal halide perovskite light emitting layer to have a low-molecular-weight organic substance in a thin film and on a surface thereof through an organic-substance-assisted nanocrystal fixing process while a metal halide perovskite solution is applied onto the substrate to coat the substrate on which the positive electrode is formed, and forming a negative electrode on the light emitting layer.

The forming of the metal halide perovskite light emitting layer in which the low-molecular-weight organic substance is included through the organic-substance-assisted nanocrystal process fixing may include preparing the metal halide perovskite solution and a low-molecular-weight organic substance solution, and applying the metal halide perovskite solution onto the substrate and coating the substrate. Here, the coating may include performing the organic-substance-assisted nanocrystal fixing process, in which both the metal halide perovskite solution and the low-molecular-weight organic substance solution are coated by dripping the low-molecular-weight organic substance solution during the coating process.

The performing the organic-substance-assisted nanocrystal fixing process may include dripping the low-molecular-weight organic substance solution before all of the solvent evaporates and then the thin film is discolored by crystallization after the coating in which the metal halide perovskite solution is applied onto the substrate begins.

The low-molecular-weight organic substance solution may be dripped within 40 to 80 seconds before the time at which all of the metal halide perovskite solvent evaporates and then the thin film is discolored by crystallization.

When a metal halide perovskite material of the metal halide perovskite light emitting layer has p-type characteristics, the low-molecular-weight organic substance may have n-type characteristics.

The low-molecular-weight organic substance may serve to transfer electrons.

The low-molecular-weight organic substance may have a molecular weight of 10 to 1000, and include a pyridine, —CN, —F, or oxadiazole.

The low-molecular-weight organic substance may be TPBI, TmPyPB, BmPyPB, BCP, PBD, Alg₃, BAlq, Bebq₂, or OXD-7.

The metal halide perovskite material may have a composition of ABX₃, A₂BX₄, ABX₄, or Aₙ₋₁PbₙI₃ₙ₊₁ (n is an integer ranging from 2 to 6), wherein A may be a monovalent organic cation, a monovalent metal cation, an amidinium-based organic ion, or a monovalent alkali metal cation (Cs⁺), B may be a divalent metal cation such as Pb, Mn, Cu, Ga, Ge, In, Al, Sb, Bi, Po, Sn, Eu, Yb, Ni, Co, Fe, Cr, Pd, Cd, Ca, Sr, or a combination thereof, and X may be a monovalent halide ion such as Cl, Br, I, or a combination thereof.

When a metal halide perovskite material of the metal halide perovskite light emitting layer has n-type characteristics, the low-molecular-weight organic substance may have p-type characteristics.

The low-molecular-weight organic substance may be TCTA or TAPC.

The low-molecular-weight organic substance solution may be prepared by dissolving the low-molecular-weight organic substance in a nonpolar organic solvent.

A concentration of the low-molecular-weight organic substance solution may be 0.001 wt % to 5 wt %.

The nonpolar organic solvent may be chloroform, chlorobenzene, toluene, dichloroethane, dichloromethane, ethyl acetate, or xylene.

In another aspect of the present invention, a metal halide perovskite light emitting device is provided. The metal halide perovskite light emitting device may include a substrate having a positive electrode formed on an upper part thereof, a metal halide perovskite light emitting layer coated through an organic-substance-assisted nanocrystal fixing process in which a low-molecular-weight organic substance is dripped while applying a metal halide perovskite solution onto the substrate to coat the substrate on which the positive electrode is formed, and a negative electrode positioned on a metal halide perovskite light emitting layer spin-coated with the low-molecular-weight organic substance.

When a metal halide perovskite material of the metal halide perovskite light emitting layer has p-type characteristics, the low-molecular-weight organic substance may have n-type characteristics.

The low-molecular-weight organic substance may serve to transfer electrons.

The low-molecular-weight organic substance may have a molecular weight of 10 to 1000, and include a pyridine, —CN, —F, or oxadiazole.

The low-molecular-weight organic substance may be TPBI, TmPyPB, BmPyPB, BCP, PBD, Algₐ, BAlq, Bebq₂, or OXD-7.

The metal halide perovskite material may have a composition of ABX₃, A₂BX₄, ABX₄, or Aₙ₋₁PbₙI₃ₙ₊₁ (n is an integer ranging from 2 to 6), wherein A may be a monovalent organic cation, a monovalent metal cation, an amidinium-based organic ion, or a monovalent alkali metal cation (Cs⁺), B may be a divalent metal cation such as Pb, Mn, Cu, Ga, Ge, In, Al, Sb, Bi, Po, Sn, Eu, Yb, Ni, Co, Fe, Cr, Pd, Cd, Ca, Sr, or a combination thereof, and X may be a monovalent halide ion such as Cl, Br, I, or a combination thereof.

When a metal halide perovskite material of the metal halide perovskite light emitting layer has n-type characteristics, the low-molecular-weight organic substance may have p-type characteristics.

The low-molecular-weight organic substance may be TCTA or TAPC.

### BRIEF DESCRIPTION OF THE DRAWINGS

FIG. 1 is a schematic view illustrating a coating method by dripping a low-molecular-weight organic substance solution during coating of a metal halide perovskite light emitting layer according to an embodiment of the present invention.

FIG. 2 is a graph illustrating the time at which a low-molecular-weight organic substance solution according to an embodiment of the present invention is dripped.

FIG. 3 illustrates structural formulas of low-molecular-weight organic substances according to an embodiment of the present invention.

FIG. 4 is scanning electron microscope (SEM) images of CH₃NH₃PbBr₃ films according to Examples 1 to 3 and Comparative Example of the present invention.

FIG. 5 is scanning electron microscope (SEM) images of CH₃NH₃PbBr₃ films according to Experimental Examples 1 to 5 and Comparative Example of the present invention.

FIG. 6A is a graph illustrating the photoluminescence (PL) spectra of CH₃NH₃PbBr₃ films according to experimental examples of the present invention.

FIG. 6B is an energy level diagram illustrating a result obtained by measuring CH₃NH₃PbBr₃ films according to experimental examples of the present invention by ultraviolet photoelectron spectroscopy (UPS).

FIG. 6C is a graph illustrating the results obtained by analyzing a trap density of states in electron only devices with CH₃NH₃PbBr₃ according to experimental examples of the present invention.

FIG. 6D is a graph illustrating the result obtained by measuring current density vs. voltage of electron only devices with CH₃NH₃PbBr₃ according to experimental examples of the present invention.

FIG. 6E is a graph illustrating the result obtained by measuring current efficiency vs. current density of light emitting diodes with CH₃NH₃PbBr₃ according to experimental examples of the present invention.

FIG. 6F is a graph illustrating the electroluminescence (EL) spectra of light emitting diodes with CH₃NH₃PbBr₃ according to experimental examples of the present invention.

FIG. 7 is an image illustrating an ABX₃ type crystal structure of a metal halide perovskite according to the present invention.

FIG. 8 is a schematic view illustrating that a low-molecular-weight organic substance according to the present invention is positioned at the grain boundary of a metal halide perovskite light emitting layer.

FIG. 9 is a schematic view illustrating that a low-molecular-weight organic substance according to the present invention is adsorbed on the surface of a metal halide perovskite light emitting layer.

### DETAILED DESCRIPTION OF EXEMPLARY EMBODIMENTS

Hereinafter, embodiments of the present invention will be described in detail with reference to the accompanying drawings as follows.

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention.

It will be understood that when an element such as a layer, a region or a substrate is referred to as being “on” another element, it can be directly on the other element or intervening elements may be present.

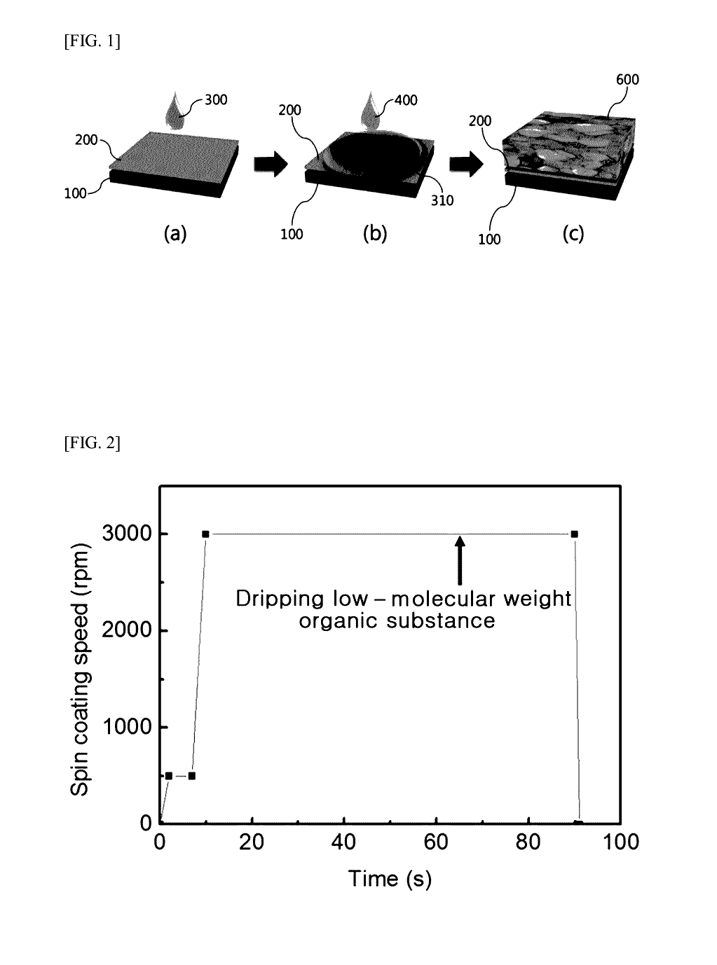

FIG. 1 is a schematic view illustrating an organic-substance-assisted nanocrystal fixing process, that is, a coating method by dripping a low-molecular-weight organic substance solution before a solvent evaporates from a light emitting layer during coating of a metal halide perovskite light emitting layer according to an exemplary embodiment of the present invention.

Referring to FIG. 1, a method for manufacturing a metal halide perovskite light emitting device including a metal halide perovskite light emitting layer coated by dripping a low-molecular-weight organic substance solution during coating of a perovskite light emitting layer according to an exemplary embodiment of the present invention (an organic-substance-assisted nanocrystal fixing process) will be described.

The “organic-substance-assisted nanocrystal fixing method” used herein refers to a process of applying a low-molecular-weight organic substance solution through dripping or drop-on-demand-type jet printing before a solvent completely evaporates, that is, before a thin film is discolored by crystallization after application of a metal halide perovskite solution onto a substrate begins, and preferably, within 40 to 80 seconds after coating with a metal halide perovskite begins, which provides an effect of adjusting a metal halide nanocrystal that is being applied to have a small size.

The method of manufacturing a metal halide perovskite light emitting device according to an exemplary embodiment of the present invention may include preparing a substrate 100 in which a positive electrode 200 is formed on an upper part thereof, forming a metal halide perovskite light emitting layer 600, which includes coating in which a low-molecular-weight organic substance is dripped onto a perovskite layer forming a thin film on the substrate 100 on which the positive electrode 200 is formed, and forming a negative electrode (not shown) on the light emitting layer 600.

More specifically, first, a substrate 100 in which a positive electrode 200 is formed on the upper part thereof may be prepared. The positive electrode 200 may be a transparent electrode and may be formed through sputtering, a solution process, or vacuum deposition. For example, the positive electrode 200 may be a metal oxide electrode (ITO or IZO), a graphene electrode, a metal nanowire electrode, or a conductive polymer electrode, but the present invention is not limited thereto.

Next, a hole injection layer (not shown) may be formed on the substrate 100 on which the positive electrode 200 is formed. For example, a conductive polymer material having a conductivity of 10⁻¹ S/cm or less (for example, polyethylenedioxythiophene (PEDOT):polystyrene sulfonate (PSS), polyaniline (PANI):polystyrene sulfonate (PSS), polyethylenedioxythiophene (PEDOT):polystyrene sulfonate (PSS):perfluorinated ionomer (PFI), and the like) may be spin-coated on the substrate 100 on which the positive electrode 200 is formed. In this case, heat treatment may be performed after the spin coating. The heat treatment may be performed under a condition of a temperature of 50 to 200° C. for 1 to 60 min. Also, the thickness of a formed hole injection layer (not shown) may be 10 nm to 300 nm.

Next, a metal halide perovskite light emitting layer 600 in which a low-molecular-weight organic substance is spin-coated on the formed hole injection layer (not shown) may be formed. In this case, metal halide perovskites have a crystal structure in which a core metal (M) is positioned in the center, six halogen elements (X) are positioned at all faces of a hexahedron as a face-centered cubic (FCC) structure, and eight organic ammonium (RNH₃) cations are positioned at all vertexes of the hexahedron as a body-centered cubic (BCC) structure (refer to FIG. 7).

In this case, the hexahedron has all faces formed at angles of 90°, and a tetragonal structure in which sides have the same lengths in width and height directions and a different length in a depth direction and a cubic structure in which sides have the same lengths in width, height and depth directions are included.

Therefore, a two-dimensional structure according to an embodiment of the present invention is a nanocrystal structure of a metal halide perovskite in which a core metal (M) is positioned in the center, six halogen elements (X) are positioned at all faces of a hexahedron as a face-centered cubic (FCC) structure, and eight organic ammonium (RNH₃) cations are positioned at all vertexes of the hexahedron as body-centered cubic (BCC) structure, and thus is defined as a structure in which the sides have the same lengths in width and height directions and a length in a depth direction at least 1.5 times the lengths in width and height directions.

The metal halide perovskite light emitting layer 600 may be formed by coating in which a low-molecular-weight organic substance solution, which is a salient feature of the present invention, is dripped onto a metal halide perovskite light emitting layer before a light emitting layer being coated is dried.

First, a metal halide perovskite solution 300 and a low-molecular-weight organic substance solution 400 may be prepared. Next, a coating process may be performed by applying the metal halide perovskite solution 300 onto a substrate. In this case, spin-coating, dip coating, shear coating, bar coating, slot-die coating, inkjet printing, nozzle printing, electrohydrodynamic jet printing, or spray coating may be used as a coating method.

Then, a thin film may be formed by adjusting the size of grains in the metal halide perovskite after applying the low-molecular-weight organic substance solution in a small amount by dripping or spraying liquid droplets through a printer during the coating process. At this time, a metal halide perovskite film throughout which the low-molecular-weight organic substance is distributed is formed and then crystallized, thereby forming a metal halide perovskite light emitting layer 600 in which the low-molecular-weight organic substance is positioned at a grain boundary and on the surface (FIG. 1C).

Dripping the low-molecular-weight organic substance solution 400 may be performed before a solvent completely evaporates after coating of the substrate by applying the metal halide perovskite solution begins (that is, before a thin film is discolored by crystallization), preferably, within 40 to 80 seconds after coating with a metal halide perovskite begins.

A metal halide perovskite material of the metal halide perovskite light emitting layer 600 may have a perovskite crystal structure of a combination of an organic substance and an inorganic substance. The organic substance and the inorganic substance in the metal halide perovskite material of the metal halide perovskite light emitting layer 600 may be composed of CH₃NH₃ and Pb, X, respectively, but the present invention is not limited thereto. Here, X may be Cl, Br, I, or a combination thereof.

X (a halogen element) used as the metal halide perovskite material of the metal halide perovskite light emitting layer 600 may be one or at least two or more elements. For example, the metal halide perovskite material may be CH₃NH₃PbX₃. Here, X may be Cl, Br, I, or a combination thereof.

For example, the metal halide perovskite material may be CH₃NH₃PbBr₃, CH₃NH₃PbBr₃₋ₓIₓ, or CH₃NH₃PbBr₃₋ₓClₓ. The metal halide perovskite may have a structure of A₂BX₄, ABX₄, or Aₙ₋₁PbₙI₃ₙ₊₁ (n is an integer ranging from 2 to 6), all of which have a lamellar-type two-dimensional structure. Here, A is an organic ammonium material, B is a metal material, and X is a halogen element.

For example, A may be (CH₃NH₃)ₙ, ((CₓH₂ₓ₊₁)ₙNH₃)₂(CH₃NH₃)ₙ, (RNH₃)₂, (CₙH₂ₙ₊₁NH₃)₂, (CF₃NH₃), (CF₃NH₃)ₙ, ((CₓF₂ₓ₊₁)ₙNH₃)₂(CF₃NH₃)ₙ, ((CₓF₂ₓ₊₁)ₙNH₃)₂, or (CnF₂ₙ₊₁NH₃)₂ (n is an integer greater than or equal to 1), and B may be a divalent transition metal, a rare earth metal, an alkaline earth metal, Pb, Sn, Ge, Ga, In, Al, Sb, Bi, Po, or a combination thereof. In this case, the rare earth metal may, for example, be Ge, Sn, Pb, Eu, or Yb. Also, the alkaline earth metal may, for example, be Ca or Sr. In addition, X may be Cl, Br, I, or a combination thereof.

The metal halide perovskite solution 300 may be prepared by mixing CH₃NH₃Br and PbBr₂ at a ratio of 1.05:1 to 1:1 and dissolving the resulting mixture in a polar organic solvent. For example, the polar organic solvent may be dimethyl sulfoxide or dimethyl formamide. For example, the metal halide perovskite solution 300, CH₃NH₃PbBr₃, may be prepared by mixing CH₃NH₃Br and PbBr₂ at a ratio of 1.05:1 and dissolving the resulting mixture in dimethyl sulfoxide (DMSO) at 40% by weight.

When a metal halide perovskite material of the metal halide perovskite light emitting layer 600 has p-type characteristics, a low-molecular-weight organic substance having n-type characteristics may be used as the low-molecular-weight organic substance, but the present invention is not limited thereto.

The low-molecular-weight organic substance may be an n-type organic substance which can serve to transfer electrons. For example, a low-molecular-weight organic substance having n-type characteristics may be added to a metal halide perovskite light emitting layer 600 with CH₃NH₃PbBr₃ having p-type characteristics. The low-molecular-weight organic substance may have a molecular weight of 10 to 1000, and include a pyridine, —CN, —F, or oxadiazole. For example, the low-molecular-weight organic substance may be 1,3,5-tris(2-N-phenylbenzimidazolyl)benzene (TPBI), 1,3,5-Tri(m-pyrid-3-yl-phenyl)benzene (TmPyPB), 1,3-bis(3,5-dipyrid-3-yl-phenyl)benzene (BmPyPB), 2,9-dimethyl-4,7-diphenyl-1,10-phenanthroline (BCP), 2-(4-biphenylyl)-5-phenyl-1,3,4-oxadiazole (PBD), tris-(8-hydroxyquinoline)aluminum (Alq3), aluminum (III) bis(2-methyl-8-quinolinato)-4-phenylphenolate (BAlq), bis(10-hydroxybenzo[h]quinolinato)beryllium (Bebq2), or 1,3-bis[2-(4-tert-butylphenyl)-1,3,4-oxadiazo-5-yl]benzene (OXD-7).

The low-molecular-weight organic substance may be the same substance as an electron transport layer (not shown) that will be described below.

The ‘low-molecular-weight organic substance’ with which the metal halide perovskite light emitting layer 600 is coated, which is a salient feature of the present invention, is positioned at a grain boundary in the metal halide perovskite crystal structure to prevent grains from growing by reducing interaction between grains. Also, a low-molecular-weight organic substance having n-type characteristics is positioned at a grain boundary in a metal halide perovskite so that a metal halide perovskite light emitting layer 600 having p-type characteristics has intrinsic properties, electrical characteristics is enhanced, and electrons and holes are balanced. Therefore, a low-molecular-weight organic substance according to the present invention is added to a grain boundary within a metal halide perovskite light emitting layer 600 to reduce the size of grains in a metal halide perovskite, to improve electrical characteristics by the effect of defect passivation of a metal halide perovskite, and to resolve imbalance of electrons and holes by nonpolar electrical characteristics, thereby exhibiting an effect of overcoming limitations in application of a metal halide perovskite light emitting diode.

When a metal halide perovskite material of the metal halide perovskite light emitting layer 600 has n-type characteristics, a low-molecular-weight organic substance having p-type characteristics may be used as the low-molecular-weight organic substance, but the present invention is not limited thereto. The low-molecular-weight organic substance having p-type characteristics may be di-[4-(N,N-ditolyl-amino)-phenyl]cyclohexane (TAPC) or 4,4′,4″-tri(N-carbazolyl)triphenylamine (TCTA).

The low-molecular-weight organic substance solution 400 may be prepared by dissolving a low-molecular-weight organic substance in a nonpolar organic solvent. The nonpolar organic solvent may be chloroform, chlorobenzene, toluene, dichloroethane, dichloromethane, ethyl acetate, or xylene.

A concentration of the low-molecular-weight organic substance solution 400 may be 0.001 wt % to 5 wt %. When the concentration is less than 0.001 wt %, an effect of trap passivation and the balance between electrons and holes by a low-molecular-weight organic substance may not be exhibited. When the concentration is greater than or equal to 5 wt %, a low-molecular-weight organic substance that is not positioned at a grain boundary in a metal halide perovskite may be stacked thicker (>20 nm) on the surface, which decreases efficiency of a device. When the thickness of a low-molecular-weight organic substance on the surface is less than 10 nm, as is preferable, efficiency of a device may be high.

The thickness of the metal halide perovskite light emitting layer 600 may be 10 nm to 900 nm.

Next, an electron transport layer (not shown) may be formed on the metal halide perovskite light emitting layer 600. For example, a material of the electron transport layer (not shown) may be formed by depositing 1,3,5-tris(1-phenyl-1H-benzimidazol-2-yl)benzene (TPBI). The thickness of the electron transport layer (not shown) may be 30 nm to 60 nm.

A negative electrode may be formed on the electron transport layer (not shown).

### Example 1

Formation of a Metal Halide Perovskite Light Emitting Layer Through Coating by Dripping a Low-Molecular-Weight Organic Substance Solution (an Organic-Substance-Assisted Nanocrystal Fixing Process)

First, CH₃NH₃Br and PbBr₂ were mixed at a ratio of 1.05:1 and the resulting mixture was dissolved in dimethyl sulfoxide (DMSO) at 40% by weight to prepare a CH₃NH₃PbBr₃ solution.

Next, TPBI was dissolved in chloroform at 0.03% by weight to prepare a TPBI solution.

Then, a conductive polymer material, PEDOT:PSS:PFI (a weight ratio of 1:6:25.4), was spin-coated with the CH₃NH₃PbBr₃ solution thereon. The spin coating was continued by dripping the TPBI solution at 65 seconds after starting the spin-coating to form a CH₃NH₃PbBr₃ layer in which the low-molecular-weight organic substance was included.

### Example 2

Formation of a Metal Halide Perovskite Light Emitting Layer Through Coating by Dripping a Low-Molecular-Weight Organic Substance Solution (an Organic-Substance-Assisted Nanocrystal Fixing Process)

A metal halide perovskite light emitting layer was formed in the same manner as in Example 1, except that TCTA was used as a low-molecular-weight organic substance instead of TPBI.

### Example 3

Formation of a Metal Halide Perovskite Light Emitting Layer Through Coating by Dripping a Low-Molecular-Weight Organic Substance Solution (an Organic-Substance-Assisted Nanocrystal Fixing Process)

A metal halide perovskite light emitting layer was formed in the same manner as in Example 1, except that CBP was used as a low-molecular-weight organic substance instead of TPBI.

### Comparative Example

Formation of a Metal Halide Perovskite Light Emitting Layer in which a Low-Molecular-Weight Organic Substance is not Included

A metal halide perovskite light emitting layer was formed in the same manner as in Example 1, except that no low-molecular-weight organic substance was added and only chloroform was added as a control group.

### Experimental Example 1

Characteristics of Metal Halide Perovskite Light Emitting Layers to which TPBI is Added as an Organic Substance Based on Concentrations

A metal halide perovskite light emitting layer was formed in the same manner as in Example 1, except that TPBI was added at 0.01% by weight.

### Experimental Example 2

Characteristics of Metal Halide Perovskite Light Emitting Layers to which TPBI is Added as an Organic Substance Based on Concentrations

A metal halide perovskite light emitting layer was formed in the same manner as in Example 1.

### Experimental Example 3

Characteristics of Metal Halide Perovskite Light Emitting Layers to which TPBI is Added as an Organic Substance Based on Concentrations

A metal halide perovskite light emitting layer was formed in the same manner as in Example 1, except that TPBI was added at 0.05% by weight.

### Experimental Example 4

Characteristics of Metal Halide Perovskite Light Emitting Layers to which TPBI is Added as an Organic Substance Based on Concentrations

A metal halide perovskite light emitting layer was formed in the same manner as in Example 1, except that TPBI was added at 0.07% by weight.

### Experimental Example 5

Characteristics of Metal Halide Perovskite Light Emitting Layers to which TPBI is Added as an Organic Substance Based on Concentrations

A metal halide perovskite light emitting layer was formed in the same manner as in Example 1, except that TPBI was added at 0.1% by weight.

FIG. 2 is a graph illustrating the time at which a low-molecular-weight organic substance solution according to an embodiment of the present invention is dripped.

Referring to FIG. 2, a low-molecular-weight organic substance solution may be dripped during coating with a metal halide perovskite solution. For example, the low-molecular-weight organic substance solution may be dripped within 40 to 80 seconds after spin coating begins with application of the metal halide perovskite solution to a substrate.

For example, the low-molecular-weight organic substance solution may be dripped within 60 to 70 seconds after spin coating begins with application of the metal halide perovskite solution to a substrate.

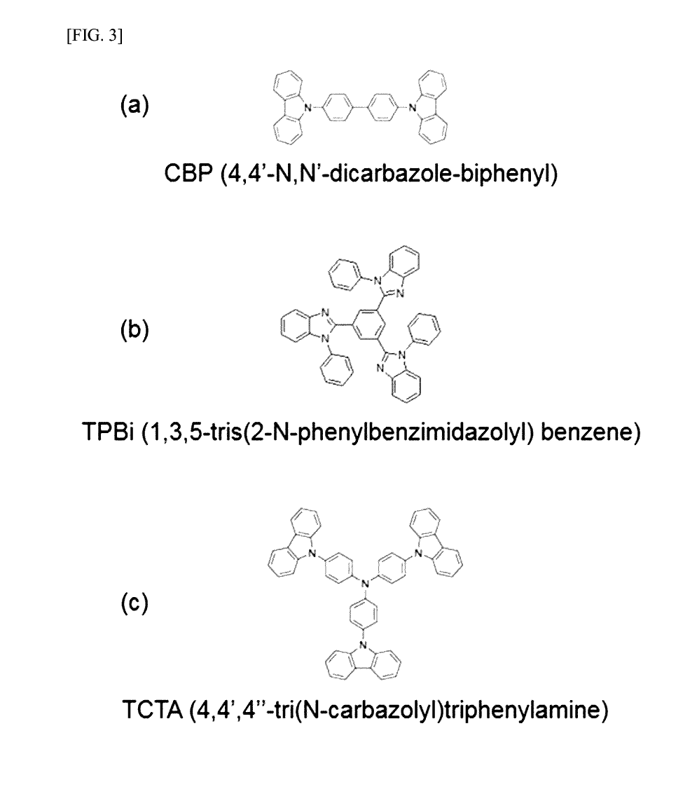

FIG. 3 illustrates structural formulas of low-molecular-weight organic substances according to an embodiment of the present invention.

Referring to FIG. 3, the low-molecular-weight organic substance may be an n-type organic substance which can serve to transfer electrons. For example, a low-molecular-weight organic substance having n-type characteristics may be added to a metal halide perovskite light emitting layer with CH₃NH₃PbBr₃ having p-type characteristics. The low-molecular-weight organic substance may have a molecular weight of 10 to 1000, and include a pyridine, —CN, —F, or oxadiazole. For example, the low-molecular-weight organic substance may be 1,3,5-tris(2-N-phenylbenzimidazolyl)benzene (TPBI), 1,3,5-Tri(m-pyrid-3-yl-phenyl)benzene (TmPyPB), 1,3-bis(3,5-dipyrid-3-yl-phenyl)benzene (BmPyPB), 2,9-dimethyl-4,7-diphenyl-1,10-phenanthroline (BCP), 2-(4-biphenylyl)-5-phenyl-1,3,4-oxadiazole (PBD), tris-(8-hydroxyquinoline)aluminum (Alq3), aluminum (III) bis(2-methyl-8-quinolinato)-4-phenylphenolate (BAlq), bis(10-hydroxybenzo[h]quinolinato)beryllium (Bebq2), or 1,3-bis[2-(4-tert-butylphenyl)-1,3,4-oxadiazo-5-yl]benzene (OXD-7).

Meanwhile, when a metal halide perovskite material of the metal halide perovskite light emitting layer has n-type characteristics, a low-molecular-weight organic substance having p-type characteristics may be used, but the present invention is not limited thereto. For example, the low-molecular-weight organic substance may be di-[4-(N,N-ditolyl-amino)-phenyl]cyclohexane (TAPC) or 4,4′,4″-tri(N-carbazolyl)triphenylamine (TCTA) (FIG. 3C).

Meanwhile, the low-molecular-weight organic substance may be a bipolar low-molecular-weight organic substance. The bipolar low-molecular-weight organic substance may be 4,4′-N,N′-dicarbazole-biphenyl (CBP) (FIG. 3A).

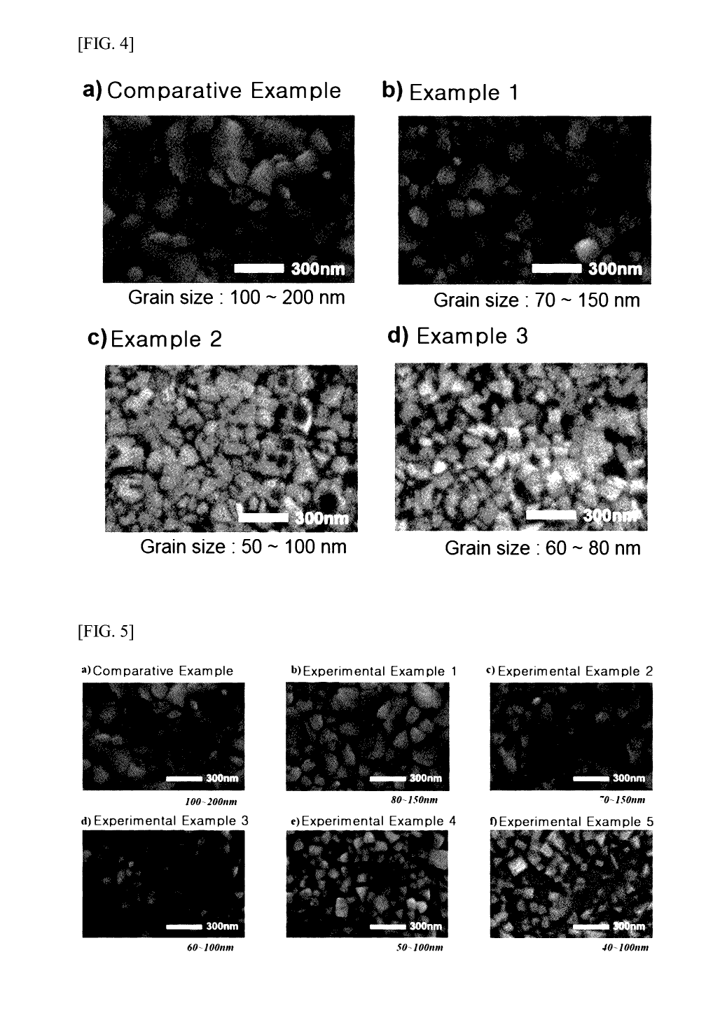

FIG. 4 is scanning electron microscope (SEM) images of CH₃NH₃PbBr₃ films according to Examples 1 to 3 and Comparative Example of the present invention.

Referring to FIG. 4, it can be understood that the sizes of grains in a metal halide perovskite decrease in the case of all of Examples 1 to 3 in which a low-molecular-weight organic substance is added to a CH₃NH₃PbBr₃ film, compared to Comparative Example in which a pure solvent (chloroform) is used.

FIG. 5 is scanning electron microscope (SEM) images of a CH₃NH₃PbBr₃ film according to Experimental Examples 1 to 5 and Comparative Example of the present invention.

Referring to FIG. 5, it can be understood that when a TPBI solution (a low-molecular-weight organic substance) has a higher concentration, the sizes of grains in the metal halide perovskite decrease (i.e., mean grain size: 80 to 150 nm for 0.01 wt % TPBI, 70 to 150 nm for 0.03 wt % TPBI, 60 to 100 nm for 0.05 wt % TPBI, 50 to 100 nm for 0.07 wt % TPBI, and 40 to 100 nm for 0.1 wt % TPBI).

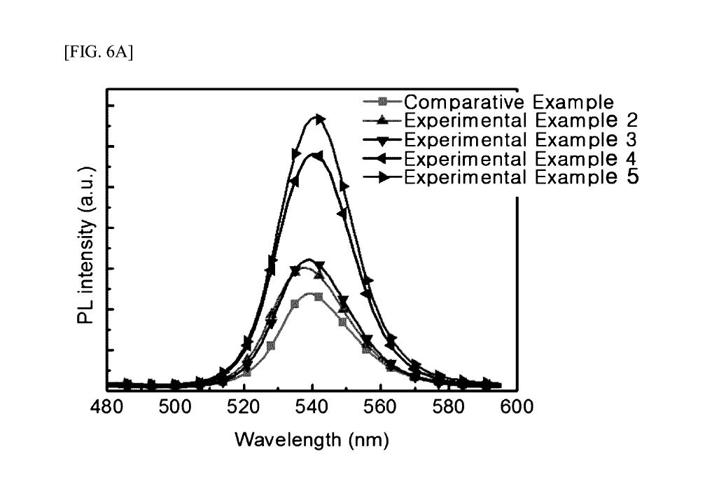

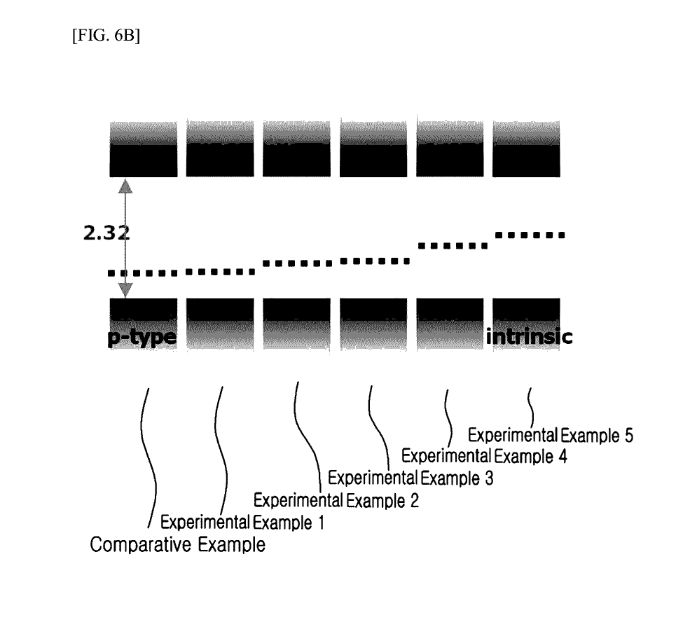

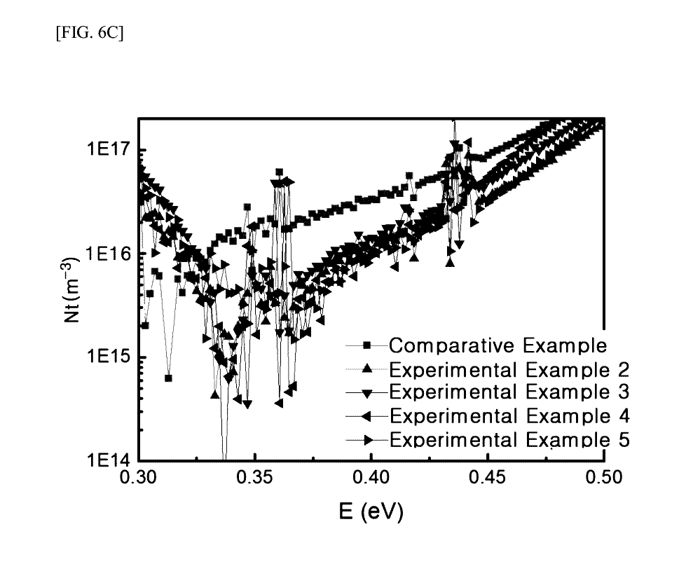

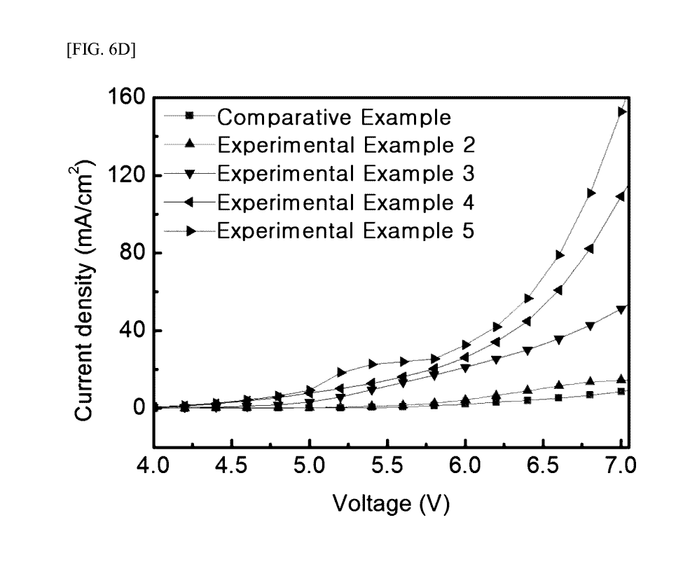

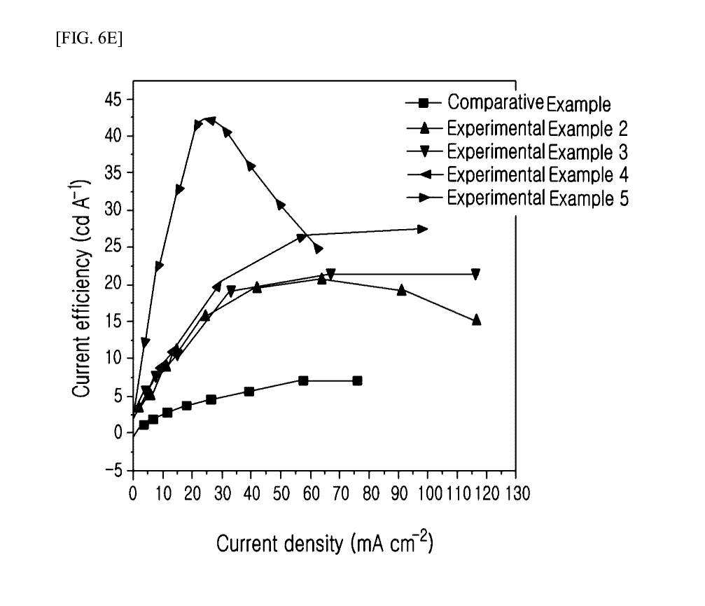

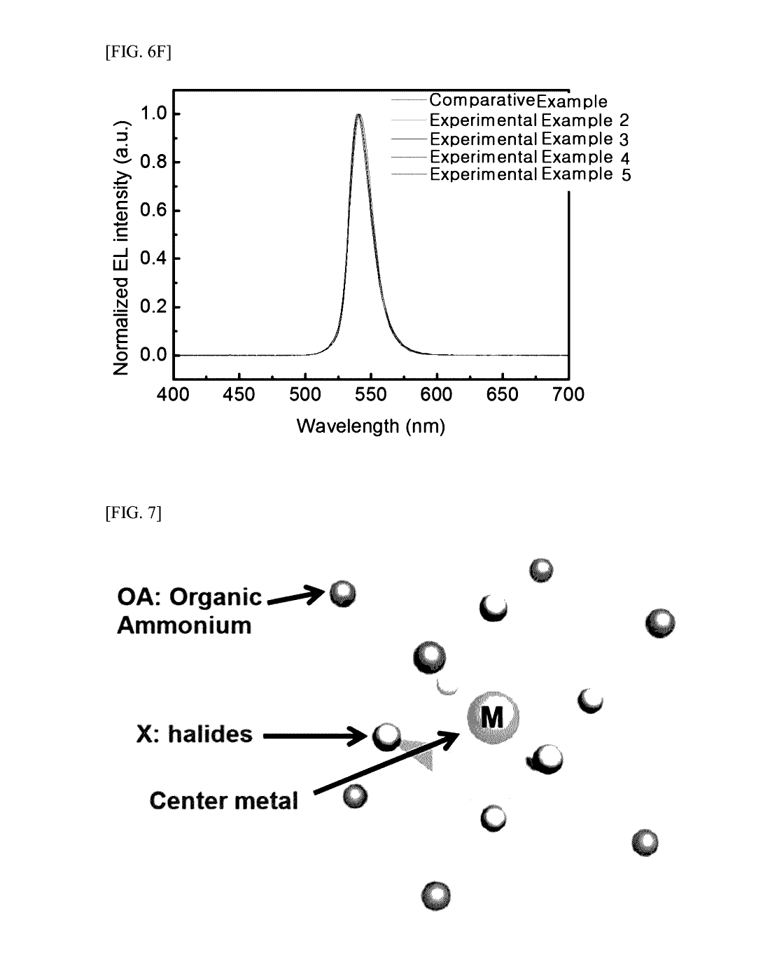

FIG. 6A is a graph illustrating the photoluminescence (PL) spectra of CH₃NH₃PbBr₃ films according to experimental examples of the present invention.

In FIG. 6A, a structure of a device to be measured using SEM is a silicon wafer, a self-assembled conductive polymer (PEDOT:PSS:PFI (a weight ratio of 1:6:25.4); 40 nm), and CH₃NH₃PbBr₃ (350 to 400 nm).

Referring to FIG. 6A, it can be seen that as a concentration of TPBI increases from 0.03 wt % to 0.1 wt %, an intensity of the PL spectrum gradually increases, which means that as an amount of a low-molecular-weight organic substance increases, a radiative recombination rate of excitons increases.

FIG. 6B is an energy level diagram illustrating a result obtained by measuring CH₃NH₃PbBr₃ films according to experimental examples of the present invention by ultraviolet photoelectron spectroscopy (UPS).

In FIG. 6B, a structure of a device to be measured using UPS is a silicon wafer, a self-assembled conductive polymer (PEDOT:PSS:PFI (a weight ratio of 1:6:25.4); 40 nm), and CH₃NH₃PbBr₃ (350 to 400 nm).

Referring to FIG. 6B, it can be seen that when TPBI having n-type characteristics is included in CH₃NH₃PbBr₃, the Fermi level changes from p-type to an intrinsic property, which is an electrical property in which electrons and holes may be transferred in balance within CH₃NH₃PbBr₃.

FIG. 6C is a graph illustrating the result obtained by analyzing a trap density of states in electron only devices with CH₃NH₃PbBr₃ according to experimental examples of the present invention.

In FIG. 6C, a structure of a device of which the trap density of states is analyzed is a glass substrate, ITO, a self-assembled conductive polymer (40 nm), CH₃NH₃PbBr₃ (350 to 400 nm), LiF (1 nm), and Al (100 nm).

Referring to FIG. 6C, it can be seen that when a TPBI solution is used, the trap density of states (tDOS) decreases compared to that when a pure solvent (chloroform) is used.

FIG. 6D is a graph illustrating the result obtained by measuring current density vs. voltage of electron only devices with CH₃NH₃PbBr₃ according to experimental examples of the present invention.

In FIG. 6D, a structure of a device of which current density vs. voltage is measured is a glass substrate, ITO, a self-assembled conductive polymer (40 nm), CH₃NH₃PbBr₃ (350 to 400 nm), LiF (1 nm), and Al (100 nm).

Referring to FIG. 6D, it can be seen through the result obtained by measuring current density vs. voltage of the electron only device that as an amount of TPBI having n-type characteristics increases, an amount of current density by electrons rapidly increases within CH₃NH₃PbBr₃.

FIG. 6E is a graph illustrating the result obtained by measuring current efficiency vs. current density of a metal halide perovskite light emitting diode with CH₃NH₃PbBr₃ according to experimental examples of the present invention.

In FIG. 6E, a structure of a device of which current efficiency vs. current density is measured is ITO, a self-assembled conductive polymer (PEDOT:PSS:PFI (a weight ratio of 1:6:25.4); 80 nm), CH₃NH₃PbBr₃ (350 to 400 nm), TPBI (50 nm), LiF (1 nm), and Al (100 nm).

Referring to FIG. 6E, it can be seen through the result obtained by measuring current efficiency vs. current density of a metal halide perovskite light emitting diode with CH₃NH₃PbBr₃ that as an amount of TPBI having n-type characteristics increases, current efficiency increases.

FIG. 6F is a graph illustrating the electroluminescence (EL) spectra of metal halide perovskite light emitting diodes with CH₃NH₃PbBr₃ according to experimental examples of the present invention.

In FIG. 6F, a structure of a device of which the electroluminescence (EL) spectrum is measured is ITO, a self-assembled conductive polymer (PEDOT:PSS:PFI (a weight ratio of 1:6:25.4); 80 nm), CH₃NH₃PbBr₃ (350 to 400 nm), TPBI (50 nm), LiF (1 nm), and Al (100 nm).

Referring to FIG. 6F, as shown by the fact that the electroluminescence (EL) spectra of metal halide perovskite light emitting diodes with CH₃NH₃PbBr₃ hardly ever change, it can be seen that TPBI has no influence on the electroluminescence (EL) spectrum when TPBI is added to CH₃NH₃PbBr₃.

FIG. 7 is an image illustrating an ABX₃ type crystal structure of a metal halide perovskite according to the present invention.

Referring to FIG. 7, metal halide perovskites have a crystal structure in which a core metal (M) is positioned in the center, six halogen elements (X) are positioned at all faces of a hexahedron as a face-centered cubic (FCC) structure, and eight organic ammonium (RNH₃) cations are positioned at all vertexes of the hexahedron as a body-centered cubic (BCC) structure.

In this case, the hexahedron has all faces formed at angles of 90°, and a tetragonal structure in which sides have the same lengths in width and height directions and a different length in a depth direction and a cubic structure in which sides have the same lengths in width, height and depth directions are included.

Therefore, a two-dimensional structure according to an embodiment of the present invention is a nanocrystal structure of a metal halide perovskite in which a core metal (M) is positioned in the center, six halogen elements (X) are positioned at all faces of a hexahedron as a face-centered cubic (FCC) structure, and eight organic ammonium (RNH₃) cations are positioned at all vertexes of the hexahedron as body-centered cubic (BCC) structure, and thus is defined as a structure in which the sides have the same lengths in width and height directions and a length in a depth direction at least 1.5 times the lengths in width and height directions.

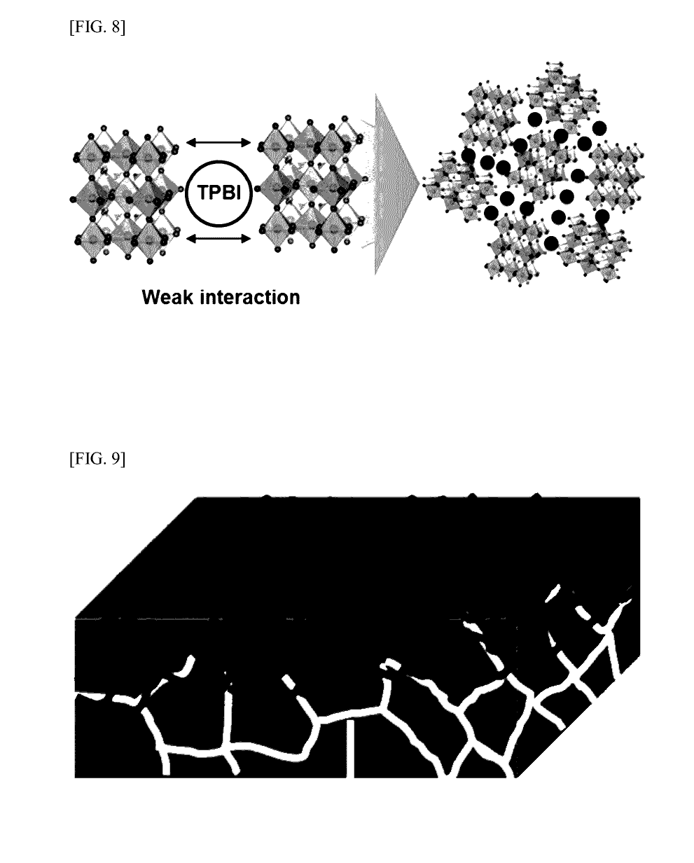

FIG. 8 is a schematic view illustrating that a low-molecular-weight organic substance according to the present invention is positioned at a grain boundary of a metal halide perovskite light emitting layer.

Referring to FIG. 8, it can be understood that when spin coating is performed by dripping a low-molecular-weight organic substance solution such as TPBI, a low-molecular-weight organic substance is positioned at the grain boundary of a metal halide perovskite light emitting layer.

FIG. 9 is a schematic view illustrating that a low-molecular-weight organic substance according to the present invention is adsorbed on the surface of a metal halide perovskite light emitting layer.

Referring to FIG. 9, it can be seen that when spin coating is performed by dripping a low-molecular-weight organic substance solution such as TPBI, a low-molecular-weight organic substance is positioned on the surface of a metal halide perovskite light emitting layer and thus covers the surface of the light emitting layer very thinly (<5 nm).

The embodiments disclosed in this specification and drawings are only examples to help understanding of the invention and the invention is not limited thereto. It is clear to those skilled in the art that various modifications based on the technological scope of the invention in addition to the embodiments disclosed herein can be made.

According to the present invention, a low-molecular-weight organic substance is included in a metal halide perovskite light emitting layer to reduce the size of grains in metal halide perovskites, to improve electrical characteristics by the effect of defect passivation on a metal halide perovskite, and to improve luminous efficiency of a thin film by reducing an exciton diffusion length by spatially trapping excitons well in decreased grains, thereby effectively improving efficiency of a metal halide perovskite light emitting diode and overcoming limitations in application.

Technological effects of the present invention are not limited to the above-described effects and other unmentioned technological effects may be clearly understood by those skilled in the art from the following descriptions.

What is claimed is:

1. A method of manufacturing a metal halide perovskite light emitting device, the method comprising:
preparing a substrate having a positive electrode formed on an upper part thereof;
forming a metal halide perovskite light emitting layer to have a low-molecular-weight organic substance in a thin film and on a surface thereof through an organic-substance-assisted nanocrystal fixing process while a metal halide perovskite solution is applied onto the substrate to coat the substrate on which the positive electrode is formed; and
forming a negative electrode on the light emitting layer.

2. The method according to claim 1, wherein the forming of the metal halide perovskite light emitting layer in which the low-molecular-weight organic substance is included through the organic-substance-assisted nanocrystal fixing process comprises:
preparing the metal halide perovskite solution and a low-molecular-weight organic substance solution; and
applying the metal halide perovskite solution onto the substrate and coating the substrate,
wherein the coating includes performing the organic-substance-assisted nanocrystal fixing process, in which the metal halide perovskite solution and the low-molecular-weight organic substance solution are coated together by dripping the low-molecular-weight organic substance solution during the coating process.

3. The method according to claim 2, wherein the performing the organic-substance-assisted nanocrystal fixing process includes dripping the low-molecular-weight organic substance solution before all of the solvent evaporates and then the thin film is discolored by crystallization after the coating in which the metal halide perovskite solution is applied onto the substrate begins.

4. The method according to claim 3, wherein the low-molecular-weight organic substance solution is dripped within 40 to 80 seconds before the time at which all of the metal halide perovskite solvent evaporates and then the thin film is discolored by crystallization.

5. The method according to claim 1, wherein, when a metal halide perovskite material of the metal halide perovskite light emitting layer has p-type characteristics, the low-molecular-weight organic substance has n-type characteristics.

6. The method according to claim 5, wherein the low-molecular-weight organic substance serves to transfer electrons.

7. The method according to claim 6, wherein the low-molecular-weight organic substance has a molecular weight of 10 to 1000, and includes a pyridine, —CN, —F, or oxadiazole.

8. The method according to claim 7, wherein the low-molecular-weight organic substance is TPBI, TmPyPB, BmPyPB, BCP, PBD, Alq₃, BAlq, Bebq₂, or OXD-7.

9. The method according to claim 5, wherein the metal halide perovskite material has a composition of ABX₃, A₂BX₄, ABX₄, or Aₙ₋₁PbₙI₃ₙ₊₁ (n is an integer ranging from 2 to 6),
wherein A is a monovalent organic cation, a monovalent metal cation, an amidinium-based organic ion, or a monovalent alkali metal cation (Cs⁺),
B is a divalent metal cation such as Pb, Mn, Cu, Ga, Ge, In, Al, Sb, Bi, Po, Sn, Eu, Yb, Ni, Co, Fe, Cr, Pd, Cd, Ca, Sr, or a combination thereof, and
X is a monovalent halide ion such as Cl, Br, I, or a combination thereof.

10. The method according to claim 1, wherein, when a metal halide perovskite material of the metal halide perovskite light emitting layer has n-type characteristics, the low-molecular-weight organic substance has p-type characteristics.

11. The method according to claim 10, wherein the low-molecular-weight organic substance is TCTA or TAPC.

12. The method according to claim 2, wherein the low-molecular-weight organic substance solution is prepared by dissolving the low-molecular-weight organic substance in a nonpolar organic solvent.

13. The method according to claim 12, wherein a concentration of the low-molecular-weight organic substance solution is 0.001 wt % to 5 wt %.

14. The method according to claim 12, wherein the nonpolar organic solvent is chloroform, chlorobenzene, toluene, dichloroethane, dichloromethane, ethyl acetate, or xylene.

15. A metal halide perovskite light emitting device, comprising:
a substrate having a positive electrode formed on an upper part thereof;
a metal halide perovskite light emitting layer coated through an organic-substance-assisted nanocrystal fixing process in which a low-molecular-weight organic substance is dripped while applying a metal halide perovskite solution onto the substrate to coat the substrate on which the positive electrode is formed; and
a negative electrode positioned on the metal halide perovskite light emitting layer spin-coated with the low-molecular-weight organic substance.

16. The metal halide perovskite light emitting device according to claim 15, wherein, when a metal halide perovskite material of the metal halide perovskite light emitting layer has p-type characteristics, the low-molecular-weight organic substance has n-type characteristics.

17. The metal halide perovskite light emitting device according to claim 16, wherein the low-molecular-weight organic substance serves to transfer electrons.

18. The metal halide perovskite light emitting device according to claim 17, wherein the low-molecular-weight organic substance has a molecular weight of 10 to 1000, and includes a pyridine, —CN, —F, or oxadiazole.

19. The metal halide perovskite light emitting device according to claim 18, wherein the low-molecular-weight organic substance is TPBI, TmPyPB, BmPyPB, BCP, PBD, Alg₃, BAlq, Bebq₂, or OXD-7.

20. The metal halide perovskite light emitting device according to claim 16, wherein the metal halide perovskite material has a composition of ABX₃, A₂BX₄, ABX₄, or Aₙ₋₁PbₙI₃ₙ₊₁ (n is an integer ranging from 2 to 6),
wherein A is a monovalent organic cation, a monovalent metal cation, an amidinium-based organic ion, or a monovalent alkali metal cation (Cs⁺),
B is a divalent metal cation such as Pb, Mn, Cu, Ga, Ge, In, Al, Sb, Bi, Po, Sn, Eu, Yb, Ni, Co, Fe, Cr, Pd, Cd, Ca, Sr, or a combination thereof, and
X is a monovalent halide ion such as Cl, Br, I, or a combination thereof.

21. The metal halide perovskite light emitting device according to claim 15, wherein, when a metal halide perovskite material of the metal halide perovskite light emitting layer has n-type characteristics, the low-molecular-weight organic substance has p-type characteristics.

22. The metal halide perovskite light emitting device according to claim 21, wherein the low-molecular-weight organic substance is TCTA or TAPC.
